(19) United States
(12) Patent Application Publication
(10) Pub. No.: US 2021/0288157 A1
(43) Pub. Date: Sep. 16, 2021

(54) SEMICONDUCTOR STORAGE DEVICE

(71) Applicant: Kioxia Corporation, Tokyo (JP)

(72) Inventor: Tetsu MOROOKA, Yokkaichi Mie (JP)

(73) Assignee: Kioxia Corporation, Tokyo (JP)

(21) Appl. No.: 17/019,456

(22) Filed: Sep. 14, 2020

(30) Foreign Application Priority Data
Mar. 11, 2020 (JP) 2020-041758

(51) Int. Cl. H01L 29/423; G11C 8/14; H01L 21/28; H01L 27/11519; H01L 27/11556; H01L 27/11524; H01L 27/11565; H01L 27/1157; H01L 27/11582

(52) U.S. Cl. CPC H01L 29/42328; G11C 8/14; H01L 29/40114; H01L 27/11519; H01L 27/11582; H01L 27/11524; H01L 27/11565; H01L 27/1157; H01L 27/11556

(57) ABSTRACT

According to one embodiment, a semiconductor storage device includes a plurality of first interconnection layers, a semiconductor layer, a first charge storage part, a conductor, and a connection portion. The plurality of first interconnection layers extend in a first direction and are arrayed in a second direction intersecting the first direction. The semiconductor layer extends in the second direction and faces the plurality of first interconnection layers in a third direction intersecting the first direction and the second direction. The first charge storage part is provided between a first interconnection layer and the semiconductor layer. The conductor extends in the second direction on an opposite side of the first charge storage part with respect to the semiconductor layer. The connection portion has a first end that is in contact with the semiconductor layer and a second end that is in contact with the conductor.

### CROSS-REFERENCE TO RELATED APPLICATION

This application is based upon and claims the benefit of priority from Japanese Patent Application No. 2020-041758, filed Mar. 11, 2020; the entire contents of which are incorporated herein by reference.

### FIELD

Embodiments described herein relate generally to a semiconductor storage device.

### BACKGROUND

A semiconductor storage device including a cell structure that is three-dimensionally laminated therein is known. For this kind of semiconductor storage device, further miniaturization and high integration have been required.

### BRIEF DESCRIPTION OF THE DRAWINGS

FIG. 1 is an enlarged cross-sectional view showing a semiconductor storage device according to a first embodiment.

FIG. 2 is a cross-sectional view taken along a line II-II shown in FIG. 1.

FIG. 3 is a cross-sectional view taken along a line III-III shown in FIG. 2.

FIG. 4 is an operation flow chart showing a cross section of the semiconductor storage device corresponding to FIG. 3.

FIG. 5 is an operation flow chart showing a cross section of the semiconductor storage device corresponding to FIG. 3.

FIG. 6 is an operation flow chart showing a cross section of the semiconductor storage device corresponding to FIG. 3.

FIG. 7 is an operation flow chart showing a cross section of the semiconductor storage device corresponding to FIG. 3.

FIG. 8 is an operation flow chart showing a cross section of the semiconductor storage device corresponding to FIG. 3.

FIG. 9 is an operation flow chart showing a cross section of the semiconductor storage device corresponding to FIG. 3.

FIG. 10 is an operation flow chart showing a cross section of the semiconductor storage device corresponding to FIG. 3.

FIG. 11 is an operation flow chart showing a cross section of the semiconductor storage device corresponding to FIG. 3.

FIG. 12 is an operation flow chart showing a cross section of the semiconductor storage device corresponding to FIG. 3.

FIG. 13 is an operation flow chart showing a cross section of the semiconductor storage device corresponding to FIG. 3.

FIG. 14 is a cross-sectional view corresponding to FIG. 3 and showing a semiconductor storage device according to a second embodiment.

FIG. 15 is an operation flow chart showing a cross section of the semiconductor storage device corresponding to FIG. 14.

FIG. 16 is an operation flow chart showing a cross section of the semiconductor storage device corresponding to FIG. 14.

FIG. 17 is an operation flow chart showing a cross section of the semiconductor storage device corresponding to FIG. 14.

FIG. 18 is an operation flow chart showing a cross section of the semiconductor storage device corresponding to FIG. 14.

FIG. 19 is an operation flow chart showing a cross section of the semiconductor storage device corresponding to FIG. 14.

FIG. 20 is an operation flow chart showing a cross section of the semiconductor storage device corresponding to FIG. 14.

FIG. 21 is an operation flow chart showing a cross section of the semiconductor storage device corresponding to FIG. 14.

FIG. 22 is a cross-sectional view showing an XY plane of a semiconductor storage device according to a third embodiment.

### DETAILED DESCRIPTION

According to one embodiment, a semiconductor storage device includes a plurality of first interconnection layers, a semiconductor layer, a first charge storage part, a conductor, and a connection portion. The plurality of first interconnection layers extend in a first direction and are arrayed in a second direction intersecting the first direction. The semiconductor layer extends in the second direction and faces the plurality of first interconnection layers in a third direction intersecting the first direction and the second direction. The first charge storage part is provided between a first interconnection layer and the semiconductor layer. The conductor extends in the second direction on an opposite side of the first charge storage part with respect to the semiconductor layer. The connection portion has a first end that is in contact with the semiconductor layer and a second end that is in contact with the conductor.

Hereinafter, semiconductor storage devices according to the embodiments will be described with reference to the drawings. In the following description, the same reference signs are given to components having the same or similar function. Duplicate description of these components may be omitted. The drawings are schematic or conceptual, and a relationship between a thickness and a width of each portion, ratios of sizes between portions, and the like are not necessarily the same as the reality.

In this specification, “connect” is not limited to a case of physical connection, and also includes a case of electrical connection. That is, “connect” is not limited to a case where two members are directly in contact with each other, and also includes a case where another member is interposed between the two members. On the other hand, “contact” means direct contact. In this specification, “overlap” and “face” are not limited to a case where two members are directly opposite to each other, and also include a case where another member is interposed between the two members. Furthermore, “overlap” and “face” also include a case where part of one of the two members and part of the other of the two members overlap each other, face each other, or the like. Additionally, “thickness” is for the sake of convenience and may be read as “dimension”. Moreover, “face each other” means that at least parts of the two members overlap each other. That is, “face each other” is not limited to a case where the two members overlap each other, and also includes a case where the two members overlap each other while parts of the two members are displaced.

Furthermore, a +X direction, a −X direction, a +Y direction, a −Y direction, a +Z direction, and a −Z direction will be defined in advance. The +X direction, the −X direction, the +Y direction, and the −Y direction are directions that are parallel to a surface of a silicon substrate 10 (to be described below). The +X direction is a direction in which bit lines BL (to be described below) extend. The −X direction is a direction opposite to the +X direction. When the +X direction and the −X direction are not distinguished, they are referred to simply as “X direction.” The +Y direction and the −Y direction are directions that intersect (e.g., are substantially orthogonal to) the X direction. The +Y direction is a direction in which word lines WL (to be described below) extend. The −Y direction is a direction opposite to the +Y direction. When the +Y direction and the −Y direction are not distinguished, they are referred to simply as “Y direction.” The +Z direction and the −Z direction are directions that intersect (e.g., are substantially orthogonal to) the X direction and the Y direction, and are a thickness direction of the silicon substrate 10. The +Z direction is a direction that is directed to a laminate 30 (to be described below) from the silicon substrate 10. The −Z direction is a direction opposite to the +Z direction. When the +Z direction and the −Z direction are not distinguished, they are referred to simply as “Z direction.” In this specification, the “+Z direction” may be referred to “up,” and the “−Z direction” may be referred to “down.” However, these expressions are for the sake of convenience, and do not regulate a gravitational direction. The X direction is an example of the “third direction.” The Y direction is an example of the “first direction.” The +Z direction is an example of the “second direction.”

### First Embodiment

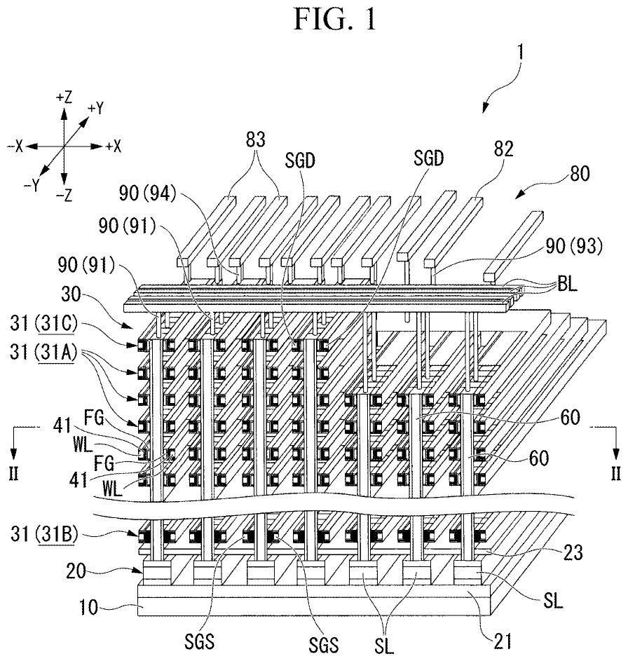

FIG. 1 is an enlarged cross-sectional view showing a semiconductor storage device 1 according to a first embodiment.

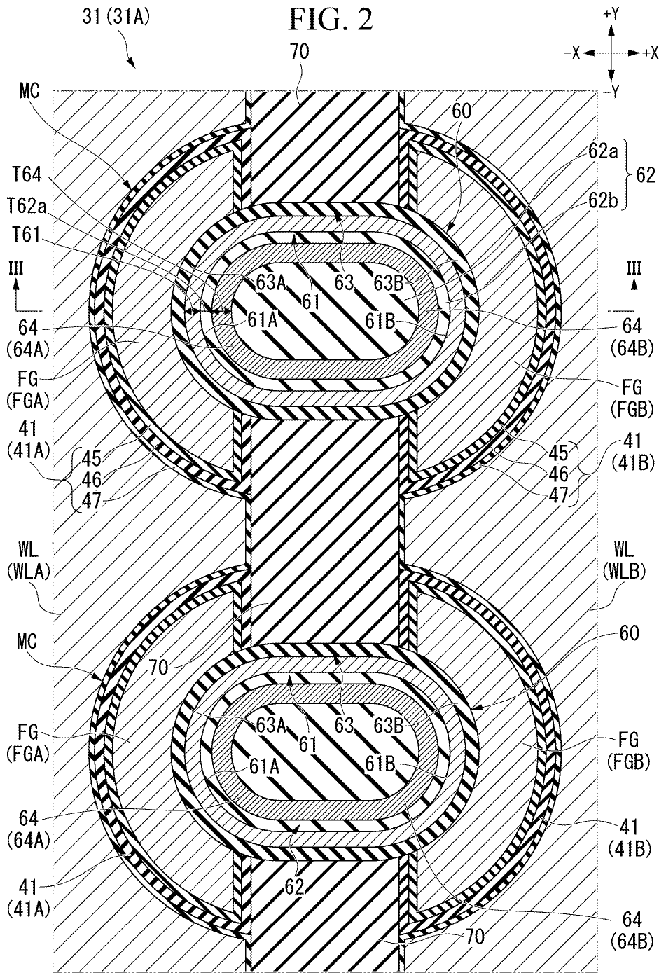

As shown in FIG. 1, the semiconductor storage device 1 is, for example, a non-volatile NAND type flash memory. The semiconductor storage device 1 includes, for example, a silicon substrate 10, a lower structure 20, a laminate 30, a plurality of pillars 60, an insulator 70 (refer to FIG. 2), an upper structure 80, and a plurality of contacts 90.

The silicon substrate 10 is a substrate that is a base of the semiconductor storage device 1. At least part of the silicon substrate 10 is formed in a plate shape having a thickness, and the thickness direction thereof is the Z direction. The silicon substrate 10 is formed of, for example, a semiconductor material including silicon (Si). In the embodiment, the silicon substrate 10 may configure a SOI (Silicon ON Insulator) substrate in which an insulating layer formed of silicon oxide or the like (not shown in the drawings) and a conductive layer that is formed of silicon or the like are laminated. The silicon substrate 10 is an example of the substrate.

The lower structure 20 is provided above the silicon substrate 10. The lower structure 20 includes, for example, a lower insulating film 21, a plurality of source lines SL, and an upper insulating film 23. The lower insulating film 21 is provided above the silicon substrate 10. The plurality of source lines SL are provided above the lower insulating film 21. The plurality of source lines SL are adjacent to one another in the X direction, and each extend in the Y direction. The upper insulating film 23 is provided above the plurality of source lines SL. An insulating member which is not shown in the drawings is provided between the source line SL and the upper insulating film 23 and between the lower insulating film 21 and the upper insulating film 23.

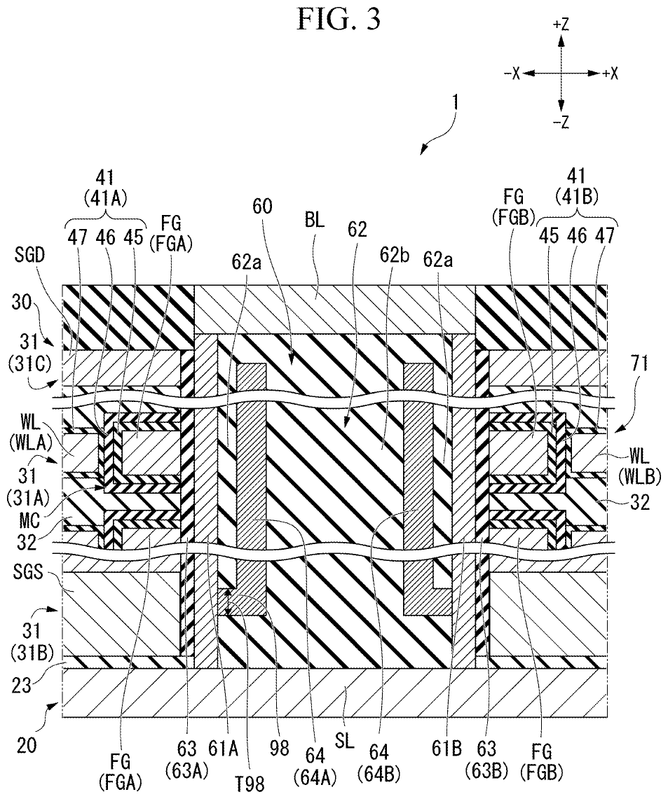

The laminate 30 is provided above the lower structure 20. The laminate 30 includes, for example, a plurality of functional layers 31 and a plurality of insulating films 32 (refer to FIG. 3). The plurality of functional layers 31 include a plurality of first functional layers 31A, one or more second functional layers 31 B, and one or more third functional layers 31C.

Each of the first functional layers 31A is laminated in the Z direction. The insulating film 32 is provided between the first functional layers 31A adjacent to each other in the Z direction. Each of the first functional layers 31A includes, for example, a plurality of word lines WL, a plurality of floating gate electrodes FG, and a plurality of block insulating films 41. The word lines WL are interconnections that are provided at the sides of the pillars 60. The word lines WL included in the first functional layer 31A are adjacent to one another in the X direction and each extend in the Y direction. In a case where the word lines WL inject electrons into the floating gate electrodes FG, the word lines WL take the electrons injected into the floating gate electrodes FG from the floating gate electrodes FG, or the like, voltages are applied by a drive circuit (not shown in the drawings), and predetermined voltages are applied to the floating gate electrodes FG connected to the word lines WL.

Each of the floating gate electrodes FG is an electrode film that is provided at the side of the pillars 60. The floating gate electrodes FG are films that have a capacity to store electric charge. The floating gate electrodes FG change a stored state of electrons in a case where voltages are applied by the word lines WL. Each floating gate electrode FG is provided between the word line WL corresponding to the floating gate electrode FG and the pillar 60 corresponding to the floating gate electrode FG. In this specification, “corresponding to” means that parts corresponding to each other are combined and therefore form an element constituting one cell structure.

Each of the block insulating films 41 is provided between the word line WL corresponding to the block insulating film 41 and the floating gate electrode FG corresponding to the block insulating film 41.

The second functional layer 31B is provided below the first functional layer 31A that is the lowermost layer. The second functional layer 31B includes, for example, a plurality of source-side select gate lines SGS. The plurality of source-side select gate lines SGS are adjacent to one another in the X direction, and each extend in the Y direction. In a case where the source-side select gate lines SGS perform conduction between the pillars 60 and the source lines SL, a voltage is applied thereto by the drive circuit (not shown in the drawings).

The third functional layer 31C is provided above the first functional layer 31A that is the uppermost layer. The third functional layer 31C includes, for example, a plurality of drain-side select gate lines SGD. The plurality of drain-side select gate lines SGD are adjacent to one another in the X direction, and each extend in the Y direction. The plurality of drain-side select gate lines SGD perform conduction between the pillars 60 and the source lines SL, a voltage is applied by the drive circuit (not shown in the drawings).

The plurality of pillars 60 are provided above the plurality of source lines SL, and each extend in the Z direction. The plurality of pillars 60 are provided away from one another in the X direction and the Y direction. For example, when viewed in the Z direction, the plurality of pillars 60 are arranged in a matrix in the X direction and the Y direction. A lower end of each pillar 60 penetrates through the upper insulating film 23 of the lower structure 20 and is connected to the source line SL.

The upper structure 80 is provided above the laminate 30. The upper structure 80 includes, for example, a plurality of bit lines BL, interconnections used for the source-side select gate lines SGS, interconnections 82 used for the word lines WL, and interconnections 83 used for the drain-side select gate lines SGD.

Each of the contacts 90 extends in the Z direction. The contacts 90 include, for example, a plurality of contacts 91 used for the pillars 60, a plurality of contacts used for the source-side select gate lines SGS (not shown in the drawings), a plurality of contacts 93 used for the word lines WL, and a plurality of contacts 94 used for the drain-side select gate lines SGD.

The contacts 91 are provided above the pillars 60. The bit lines BL are adjacent to one another in the Y direction, and each extend in the X direction. In a case where the pillar 60 provided on the outermost side in the −X direction among the plurality of pillars 60 arranged in the X direction is set to a first pillar, the odd-numbered pillars 60 are connected to common bit lines BL via the contacts 91. The even-numbered pillars 60 are connected to common bit lines BL different from the bit lines BLA via the contacts 91. That is, the pillars 60 that are adjacent to each other among the plurality of pillars 60 arranged in the X direction are not connected to the same bit line BL.

The plurality of contacts (not shown in the drawings) used for the source-side select gate lines SGS are provided above ends of the source-side select gate lines SGS in the +Y direction. Interconnection used for the source-side select gate line SGS (not shown in the drawings) are connected to the source-side select gate lines SGS via contacts used for the source-side select gate lines SGS.

The plurality of contacts 93 are provided above ends of the word lines WL in the Y direction. The interconnections 82 are provided above the contacts 93 and each extend in the Y direction. The interconnections 82 are connected to the word lines WL via the contacts 93.

The plurality of contacts 94 are provided above ends of the drain-side select gate lines SGD in the +Y direction. The interconnections 83 are provided above the contacts 94 and each extend in the Y direction. The interconnections 83 are connected to the drain-side select gate lines SGD via the contacts 94.

FIG. 2 is a cross-sectional view taken along a line II-II shown in FIG. 1. FIG. 3 is a cross-sectional view taken along a line III-III shown in FIG. 2.

As shown in FIGS. 2 and 3, the laminate 30 has a storage structure around each pillar 60 which can store information. The storage structures, each of which is provided around the pillar 60, has the same structure as each other. Consequently, in the following explanation, one pillar 60 is focused, and the configuration around the pillar 60 will be mainly described.

The word line WL includes: first word lines WLA located on the sides of the pillars 60 in the −X direction; and second word lines WLB located on the sides of the pillars 60 in the +X direction. The first word lines WLA and the second word lines WLB are adjacent to one another in the X direction, and each extend in the Y direction. The first word lines WLA and the second word lines WLB are led out, for example, in directions opposite to each other in the Y direction with respect to the pillar 60, and are controlled independently of each other. The first word lines WLA is an example of a first interconnection layer, and the second word lines WLB is an example of a second interconnection layer.

The word lines WL is formed of, for example, tungsten. A barrier metal film (not shown in the drawings) that curbs diffusion of a material of the word lines WL may be provided on surfaces of the word lines WL. A barrier metal film is formed of, for example, titanium nitride (TiN).

The word lines WL are alternately laminated in the Z direction with an insulator (for example, the insulating films 32 and 41) interposed therebetween. In the embodiment, the portion in which the word lines WL and the insulator are laminated on one pillar 60 is referred to as a cell region 71. In this case, an upper end of the cell region 71 is continued to the second functional layer 31B. A lower end of the cell region 71 is continued to the third functional layer 31C.

The floating gate electrodes FG each include: first floating gate electrodes FGA located on the sides of the pillars 60 in the −X direction; and second floating gate electrodes FGB located on the sides of the pillars 60 in the +X direction. The first floating gate electrode FGA is provided between the first word line WLA and the pillar 60. On the other hand, the second floating gate electrode FGB is provided between the second word line WLB and the pillar 60. The first floating gate electrode FGA is an example of a first charge storage part, and the second floating gate electrode FGB is an example of a second charge storage part.

The floating gate electrodes FG are formed of, for example, polysilicon. The first floating gate electrodes FGA change a stored state of electrons in a case where voltages are applied by the first word lines WLA. On the other hand, the second floating gate electrodes FGB change a stored state of electrons in a case where voltages are applied by the second word lines WLB.

In plan view when the semiconductor storage device 1 is viewed in the Z direction, the first floating gate electrodes FGA are each formed in a projected arc shape that has a center angle of, for example, approximately 180° and protrudes toward the −X direction. Particularly, as the first floating gate electrode FGA is directed from a center portion thereof in the Y direction toward the side on the +Y direction and toward the side on the −Y direction, the first floating gate electrode FGA extends in the +X direction while being curved.

In plan view, the second floating gate electrodes FGB are each formed in a projected arc shape that has a center angle of, for example, approximately 180° and protrudes toward the +X direction. Particularly, as the second floating gate electrode FGB is directed from a center portion thereof in the Y direction toward the side on the +Y direction and toward the side on the −Y direction, the first floating gate electrode FGA extends in the −X direction while being curved.

As shown in FIG. 3, the ends of the source-side select gate line SGS and the drain-side select gate line SGD which are mentioned above and are directed to a side of the pillar 60 are located closer to the pillar 60 than the end of the word line WL which is directed to a side of the pillar 60. That is, the ends of the source-side select gate line SGS and the drain-side select gate line SGD which are directed to a side of the pillar 60 overlap the floating gate electrode FG in plan view. Any one of the source-side select gate line SGS and the drain-side select gate line SGD may overlap the floating gate electrode FG in plan view. Additionally, a floating gate electrode may be provided between the source-side select gate line SGS and the pillar 60 and between the drain-side select gate line SGD and the pillar 60.

The plurality of block insulating films 41 include: first block insulating films 41A located on the sides of the pillars 60 in the −X direction; and second block insulating films 41B located on the sides of the pillars 60 in the +X direction. The first block insulating film 41A is provided between the first word lines WLA and the first floating gate electrode FGA. The second block insulating film 41B is provided between the second word lines WLB and the second floating gate electrode FGB.

Each of the first block insulating film 41A and the second block insulating film 41B is formed of, for example, three insulating films 45, 46, and 47.

The insulating film 45 is located closest to the floating gate electrode FG in the three insulating films 45, 46, and 47. The insulating film 45 covers, for example, the lateral surfaces, the upper surface, and the lower surface of the floating gate electrode FG (refer to FIG. 3). The insulating film 45 is formed of, for example, a high-k material such as silicon nitride (SiN), hafnium oxide (HfO), or the like. However, the insulating film 45 may be formed of a material containing ruthenium (Ru), aluminum (Al), titanium (Ti), zirconium (Zr), or silicon (Si).

The insulating films 46 are provided on sides opposite to the floating gate electrodes FG with respect to the insulating films 45.

The insulating film 46 covers, for example, the lateral surfaces, the upper surface, and the lower surface of the floating gate electrode FG with the insulating film 45 interposed therebetween (refer to FIG. 3). However, instead of the above constitution, the insulating film 46 may cover only the lateral surfaces of the floating gate electrodes FG, and may be provided along a boundary between the insulating film 32 and the word line WL. The insulating films 46 are formed of, for example, silicon oxide.

The insulating films 47 are provided on sides opposite to the floating gate electrodes FG with respect to the insulating films 45 and 46. The insulating films 47 are each formed along, for example, the boundary between the insulating film 32 and the word line WL and cover the lateral surfaces of the floating gate electrode FG with the insulating films 45 and 46 interposed therebetween (refer to FIG. 3). However, instead of the above constitution, like the insulating films 45 and 46, the insulating film 47 may cover, the lateral surfaces, the upper surface, and the lower surface of the floating gate electrode FG. The insulating films 47 need to be formed of a material having a high dielectric constant, and are formed of, for example, a high-k film that is an oxide film containing aluminum (Al), hafnium (Hf), or zirconium (Zr). The insulating films 47 may be formed of silicon nitride.

As shown in FIG. 2, the pillars 60 are provided between the first word lines WLA and the second word lines WLB. The pillars 60 each include, for example, a channel 61, a core insulator 62, a tunnel insulating film 63, and a back-gate electrode 64. The channel 61 is an example of a semiconductor layer. The back-gate electrode 64 is an example of a conductor.

The channel 61 extends in the Z direction over an entire length (a whole height) of the pillar 60 in the Z direction. A lower end of the channel 61 passes through the upper insulating film 23 of the lower structure 20 shown in FIG. 3, and is connected to the source line SL. On the other hand, an upper end of the channel 61 is connected to the bit line BL via the contact 91 (not shown in FIG. 3). The channel 61 is formed of a semiconductor material such as polysilicon (Poly Si) or the like. The channel 61 may be formed of, for example, polysilicon into a part of which impurities are doped. The impurities included in the channel 61 are any one selected from the group consisting of, for example, carbon, phosphorus, boron, and germanium. In a case where, for example, the channel 61 injects electrons into the floating gate electrode FG, takes the electrons injected into the floating gate electrode FG from the floating gate electrode FG, or the like, an electric current flows between the source line SL and the bit line BL.

As shown in FIG. 2, the channel 61 is formed between the first word line WLA and the second word line WLB in a ring shape in plan view (for example, an oval shape extending in the X direction). The channel 61 includes: a first channel portion 61A located on the sides of the pillars 60 in the −X direction; and a second channel portion 61B located on the sides of the pillars 60 in the +X direction. The first channel portion 61A and the second channel portion 61B are adjacent to one another in the X direction, and each extend in the Z direction.

The core insulator 62 is provided on a central side of the pillar 60 relative to the channel 61 in the X and Y directions. For example, the core insulator 62 is provided on an inner circumferential surface of the channel 61. As shown in FIG. 3, the core insulator 62 extends in the Z direction over an entire length (a whole height) of the pillar 60 in the Z direction. The core insulator 62 is formed of, for example, silicon oxide (SiO).

The tunnel insulating films 63 are at least provided along lateral surfaces of the channels 61 in the −X direction and the +X direction. The tunnel insulating films 63 include: first tunnel insulating films 63A located on the sides of the pillars 60 in the −X direction; and second tunnel insulating films 63B located on the sides of the pillars 60 in the +X direction. The first tunnel insulating film 63A is provided between the first floating gate electrode FGA and the first channel portion 61A. The second tunnel insulating film 63B is provided between the second floating gate electrode FGB and the second channel portion 61B.

In the present embodiment, the tunnel insulating films 63 are formed in a ring shape (for example, an oval shape extending in the X direction) that surrounds lateral surfaces of the channels 61 in the −X direction, the +X direction, the −Y direction, and the +Y direction. The tunnel insulating films 63 extend in the Z direction, for example, over entire lengths (whole heights) of the pillars 60 in the Z direction.

As shown in FIG. 2, in the configuration described above, the first floating gate electrode FGA, the second floating gate electrode FGB, the first block insulating film 41A, the second block insulating film 41B, the first tunnel insulating film 63A, and the second tunnel insulating film 63B correspond to the pillar 60 for each first functional layer 31A, and therefore a cell structure MC that can store electric charge at the periphery of the pillar 60 is formed. The cell structures MC, each of which corresponds to the pillar 60, are adjacent to one another in the Y direction. Accordingly, in each cell region 71, the plurality of cell structures MC are spaced apart at a distance and laminated in the Z direction.

The insulator 70 is provided in the laminate 30 and divides the first word line WLA and the second word line WLB. The insulator 70 is provided between the pillars 60 in the Y direction and extends in the Y direction between the pillars 60. The insulator 70 is provided between the first word line WLA and the second word line WLB in the X direction and divides the first word line WLA and the second word line WLB. Moreover, the insulator 70 is provided between part of the first floating gate electrode FGA and part of the second floating gate electrode FGB in the X direction and divides the first floating gate electrode FGA and the second floating gate electrode FGB.

The pillars 60 and the insulators 70 are alternately provided in the Y direction. In other words, the insulator 70 is provided between one of the pillars 60 and the other of the pillars 60 which are arrayed in the Y direction.

For this reason, the insulator 70 electrically insulates the first word line WLA from the second word line WLB in cooperation with the pillar 60. In the embodiment, the insulator 70 extends straight in the Y direction between the tunnel insulating films 63 of the cell structures MC adjacent to one another in the Y direction and is in contact with each of the tunnel insulating films 63 of the cell structures MC adjacent to one another in the Y direction. The insulator 70 is formed of, for example, an insulation material such as silicon oxide (SiO₂). Note that, in the embodiment, a so-called floating-gate cell structure MC having the floating gate electrodes FG, each of which is surrounded by the block insulating film 41, was described. The embodiment is not limited to this structure. The cell structure may be a so-called charge trap structure that includes a charge storage layer extending in the Z direction over the entirety of each word line WL.

The back-gate electrode 64 is provided at a center side (inside the core insulator 62) of the pillar 60 with respect to the channel 61 and extends in the Z direction. The back-gate electrode 64 is formed in, for example, a tubular shape. Particularly, the back-gate electrode 64 is formed in a ring shape (for example, an oval shape extending in the X direction) having a size smaller than the channel 61 in plan view. The back-gate electrode 64 includes: a first back gate 64A located on the sides of the pillars 60 in the −X direction; and a second back gate 64B located on the sides of the pillars 60 in the +X direction. The shape of the back-gate electrode 64 is not limited to the tubular shape but may be, for example, a pillar shape which is coaxially disposed at a center the pillar 60.

The first back gate 64A faces the first channel portion 61A in a state of interposing part of the core insulator 62 therebetween. The second back gate 64B faces the second channel portion 61B in a state of interposing part of the core insulator 62 therebetween. The first back gate 64A and the second back gate 64B are continued to each other in the X direction, and therefore the back-gate electrode 64 is formed in a ring shape as described above. Consequently, the portion at which the back-gate electrode 64 is provided in the core insulator 62 is divided into an outer insulator 62a and an inner insulator 62b. The outer insulator 62a is located outside the pillar 60 with respect to the back-gate electrode 64. The inner insulator 62b is located at a center side of the pillar 60 with respect to the back-gate electrode 64. In this case, the outer insulator 62a is formed in a ring shape in plan view along an inner peripheral face of the channel 61 and an outer peripheral face of the back-gate electrode 64. On the other hand, the inner insulator 62b is formed in a round shape along an inner peripheral face of the back-gate electrode 64 in plan view.

In the example shown in FIG. 2, it is preferable that the minimum thickness T64 in plan view of the back-gate electrode 64 be larger than each of the minimum thickness T62a of the outer insulator 62a and the minimum thickness T61 of the channel 61. In the shown example, the minimum thickness T61 of the channel 61 is larger than the minimum thickness T62a of the outer insulator 62a. However, the thicknesses of the back-gate electrode 64, the outer insulator 62a, and the channel 61 are suitably modifiable.

The back-gate electrode 64 is formed of, for example, silicon (polysilicon, crystalline silicon, or the like). Specifically, the back-gate electrode 64 is an N-type semiconductor having an impurity concentration of 1×10¹⁷ cm⁻³ to 1×10²¹ cm⁻³ (more preferably, 1×10¹⁸ cm⁻³ to 1×10¹⁹ cm⁻³) and has an electrical conductivity higher than that of the channel 61.

As shown in FIG. 3, the back-gate electrode 64 is formed over an entire length of the cell region 71 in vertical cross section in the Z direction. An upper end of the back-gate electrode 64 is located above the cell region 71 inside the third functional layer 31C. The upper end of the back-gate electrode 64 faces the drain-side select gate line SGD in a state of interposing the channel 61 and the outer insulator 62a therebetween. However, the upper end of the back-gate electrode 64 may be located below the drain-side select gate line SGD inside the third functional layer 31C.

A lower end of the back-gate electrode 64 is located below the cell region 71 inside the second functional layer 31B. The lower end of the back-gate electrode 64 faces the drain-side select gate line SGD in a state of interposing the channel 61 and the outer insulator 62a therebetween inside the second functional layer 31B. However, the lower end of the back-gate electrode 64 may be located above the source-side select gate line SGS inside the second functional layer 31B. Accordingly, the length of the back-gate electrode 64 in the Z direction is longer than that of the cell region 71 and is shorter than that of the channel 61. That is, both end portions of the back-gate electrode 64 in the Z direction are located outside the word line WL that is disposed at the lowermost layer and the uppermost layer (outermost of the cell region 71) among the word lines WL constituting the cell region 71. Note that, the length of the back-gate electrode 64 in the Z direction is suitably modifiable as long as the bit lines BL and the source line SL are insulated from each other and the back-gate electrode 64 extends over an entire length of the cell region 71.

A connection electrode 98 is provided at a position at which the lower end of the back-gate electrode 64 faces the source-side select gate line SGS (a position at which they overlap each other in the Z direction). The connection electrode 98 extends from the lower end of the back-gate electrode 64 toward an outer-peripheral side of the pillar 60. The connection electrode 98 is in contact with the channel 61 at one end (hereinafter, referred to as an outer-circumferential end) located at the outer-peripheral side of the pillar 60 and is in contact with the lower end of the back-gate electrode 64 at the other end located at an inner-peripheral side of the pillar 60. Particularly, the back-gate electrode 64 is connected to the source line SL with the channel 61 interposed therebetween. On the other hand, the back-gate electrode 64 is not connected to the bit line BL. The connection electrode 98 is an example of a connection portion.

In the embodiment, the connection electrode 98 protrudes from the entire periphery of the back-gate electrode 64 and is formed in a flange shape. The outer-circumferential end of the connection electrode 98 is connected to the entire periphery of the channel 61. However, the connection electrode 98 may has a configuration in which at least part of the connection electrode 98 connects the lower end of the back-gate electrode 64 to the channel 61. Additionally, as long as the connection electrode 98 is insulated from the source line SL, the connection electrode 98 may be connected to the source-side select gate line SGS at a different position in the Z direction below the cell region 71 (a position at which they do not overlap each other in the Z direction). The source-side select gate line SGS is disposed between the silicon substrate 10 and the word line WL (the word line WL located at the lowermost layer of the cell region 71) closest to the silicon substrate 10 in the word lines WL.

It is preferable that the minimum thickness T98 of the connection electrode 98 in the Z direction (refer to FIG. 3) be equal to the minimum thickness T64 of the back-gate electrode 64. However, the minimum thickness T98 of the connection electrode 98 may be larger or smaller than the minimum thickness T64 of the back-gate electrode 64.

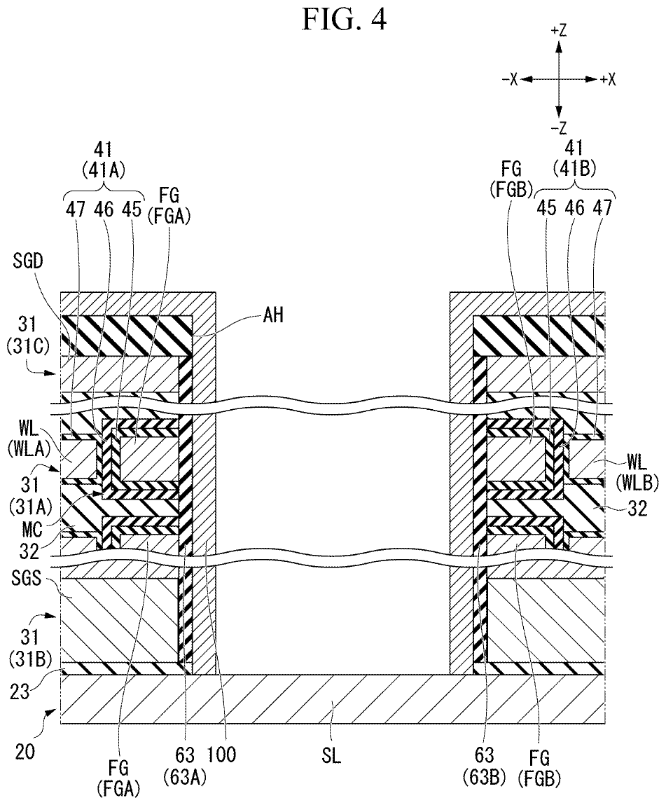

Next, a method of manufacturing the semiconductor storage device 1 will be described. FIGS. 4 to 13 are operation flow charts each showing a cross section of the semiconductor storage device 1 corresponding to FIG. 3. In the following explanation, a method of manufacturing the pillar 60 is mainly described. That is, hereinbelow, the explanation will be started in the situation in which a tunnel insulating film 63 is formed in a memory hole AH used for forming the pillar 60.

In a first process shown in FIG. 4, the channel 61 is formed on an inner peripheral face of the tunnel insulating film 63 inside the memory hole AH. Specifically, a channel interlayer 100 is mainly formed on the inner peripheral face of the tunnel insulating film 63 by a CVD (Chemical Vapor Deposition) method or the like.

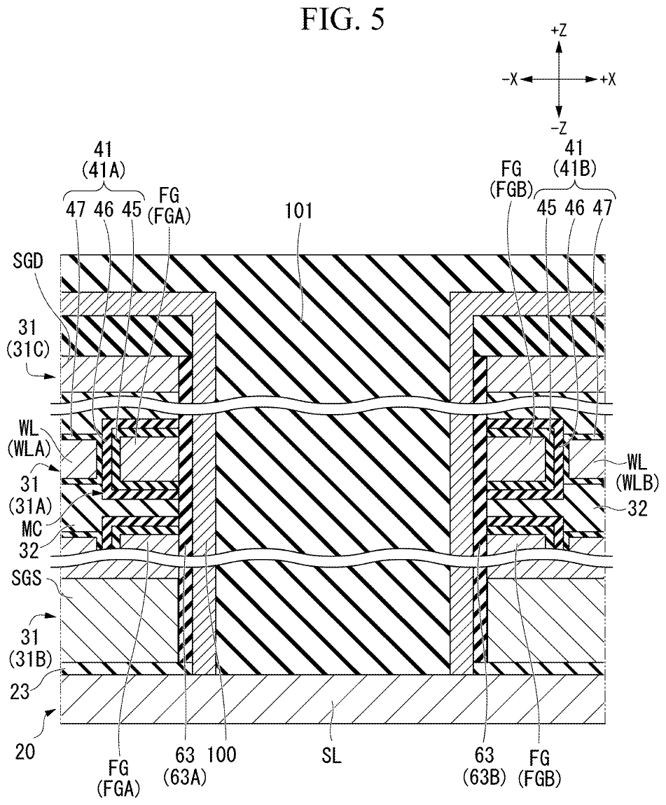

Next, in a second process shown in FIG. 5, part of the core insulator 62 (a portion located at a lower side of the back-gate electrode 64 shown in FIG. 3) is mainly formed inside the channel interlayer 100. Specifically, an insulating interlayer 101 is formed by a CVD method or the like so as to fill the inside of the memory hole.

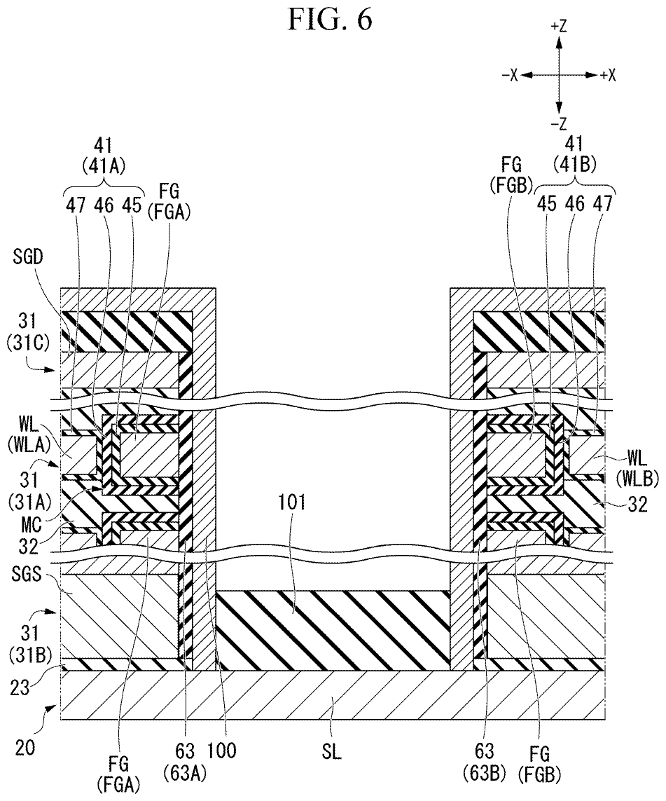

Subsequently, in a third process shown in FIG. 6, the insulating interlayer 101 is etched back by anisotropic etching such as an R1E (Reactive Ion Etching) or the like. At this time, the insulating interlayer 101 is removed until an upper end of the insulating interlayer 101 is located under an upper end of the source-side select gate line SGS.

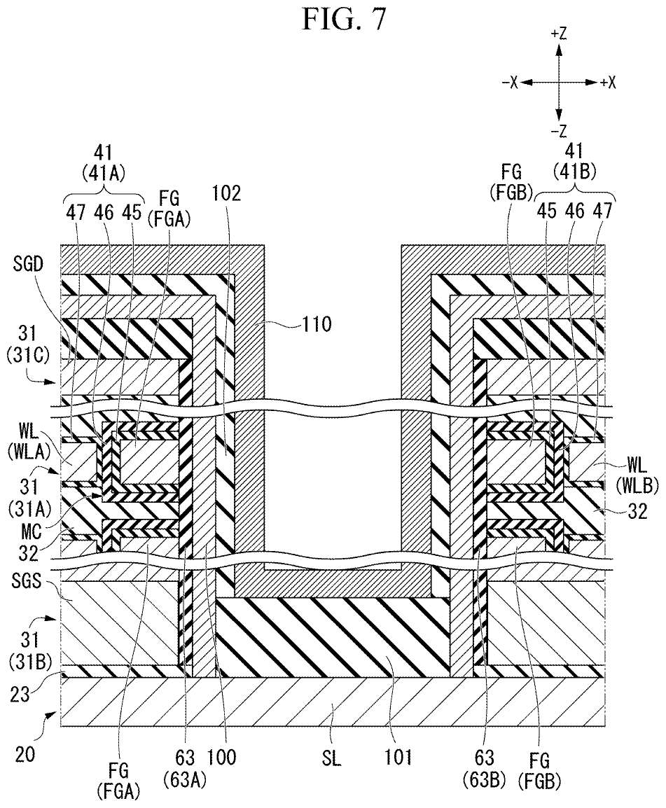

Next, in a fourth process shown in FIG. 7, the outer insulator 62a (refer to FIG. 3) is formed on an inner peripheral face of the channel interlayer 100. Specifically, an insulating interlayer 102 is formed on an upper surface of the channel interlayer 100 and on an inner peripheral face of the channel interlayer 100 by a CVD method or the like.

Subsequently, in a fifth process, a protective film 110 is formed on the insulating interlayers 101 and 102 by a CVD method or the like. The protective film 110 is formed of, for example, silicon nitride (SiN).

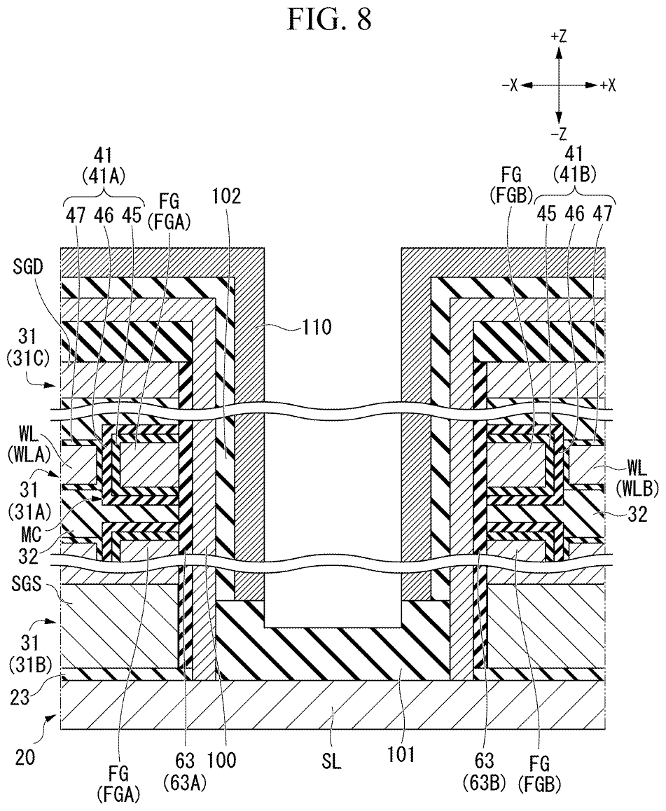

Next, in a sixth process shown in FIG. 8, a bottom portion of the protective film 110 is etched by anisotropic etching while protecting an upper portion of the protective film 110 by, for example, a cover film with a low degree of step coverage. At this time, the protective film 110 is etched in the memory hole AH until the etching is completed at a position at which the insulating interlayer 101 is exposed.

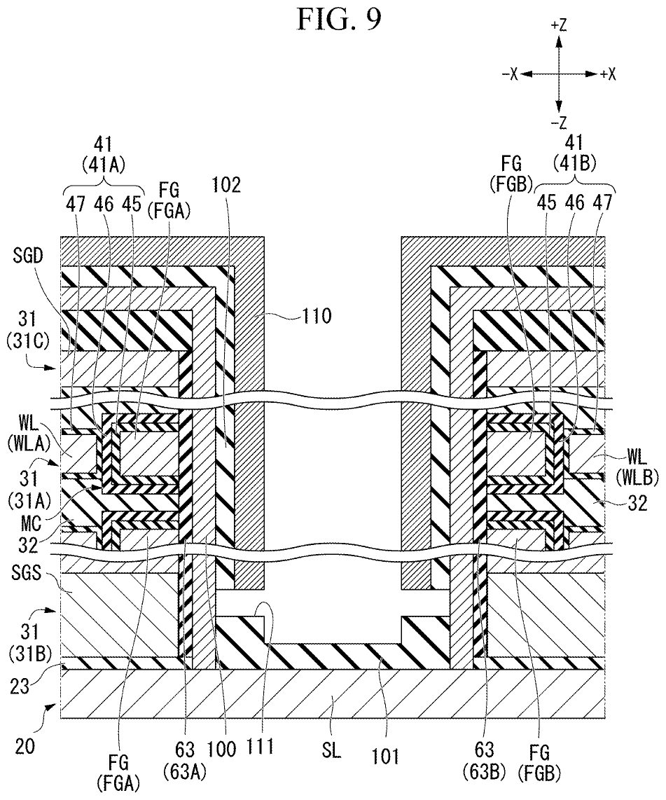

Subsequently, in a seventh process shown in FIG. 9, isotropic etching is carried out by, for example, using a chemical solution that dissolves silicon oxide, and the insulating interlayer 101 is mainly etched. At this time, an exposing hole 111 that exposes part of the channel interlayer 100 is formed on the insulating interlayer 101.

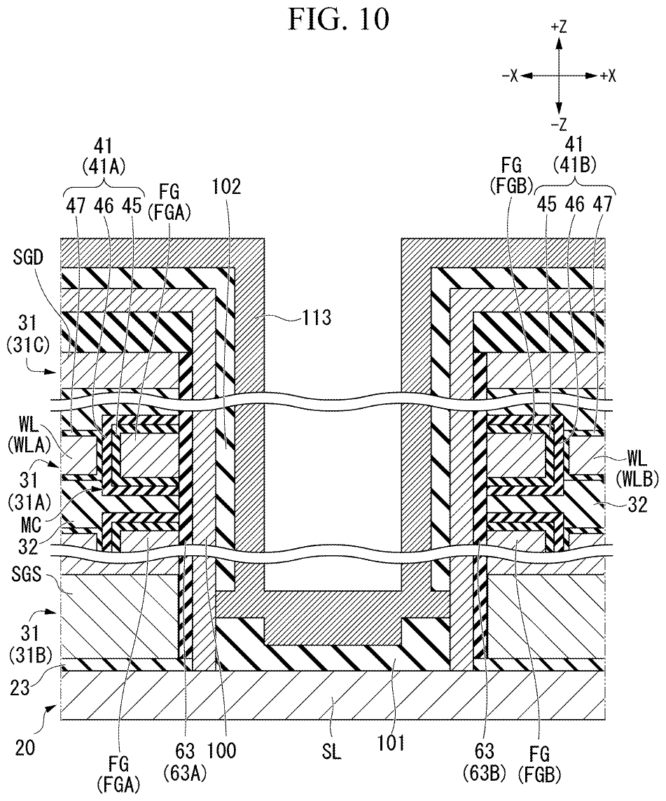

Next, in an eighth process shown in FIG. 10, isotropic etching is carried out by, for example, using a chemical solution that dissolves silicon nitride, the protective film 110 is removed, and thereafter, the back-gate electrode 64 and the connection electrode 98 are formed. Specifically, an electrode intermediate product 113 is mainly formed on the insulating interlayers 101 and 102 or inside the exposing hole 111 by a CVD method or the like.

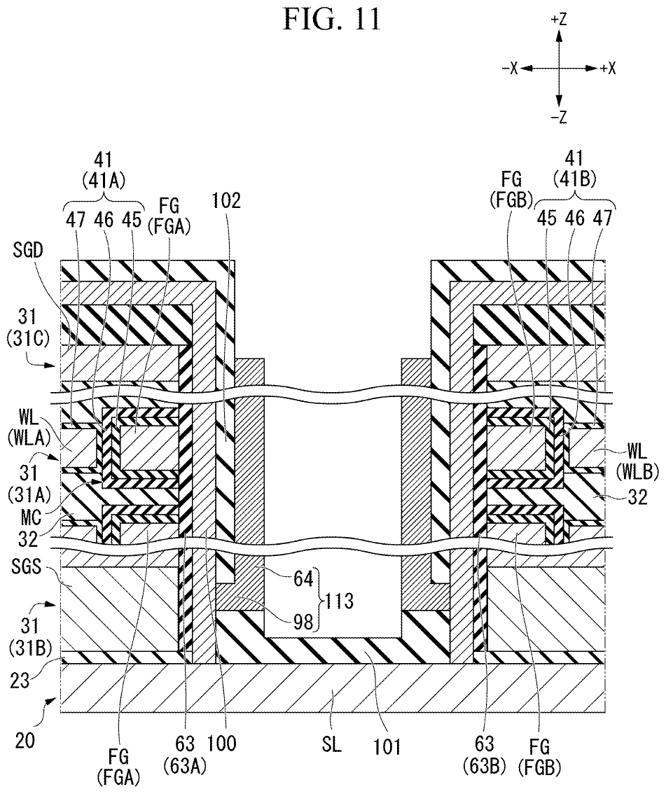

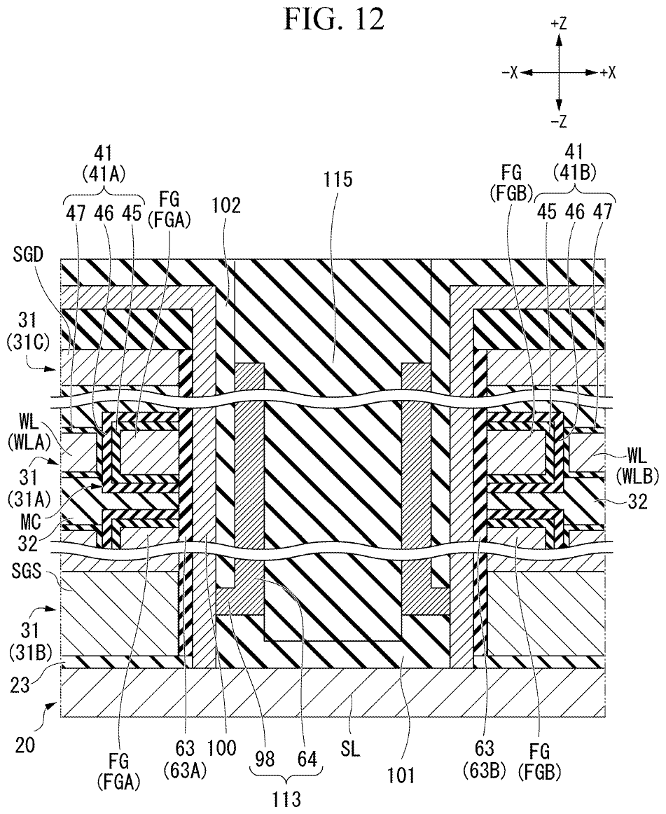

Next, in a ninth process shown in FIG. 11, if the electrode intermediate product 113, the portion located at the position except for a region at which the back-gate electrode 64 and the connection electrode 98 are to be formed is removed by anisotropic etching. Successively, in a tenth process shown in FIG. 12, an insulating interlayer 115 that is to be the core insulator 62 is formed on the electrode intermediate product 113 by a CVD method or the like. At this time, the insulating interlayer 115 is formed so as to fill the inside of the memory hole AH.

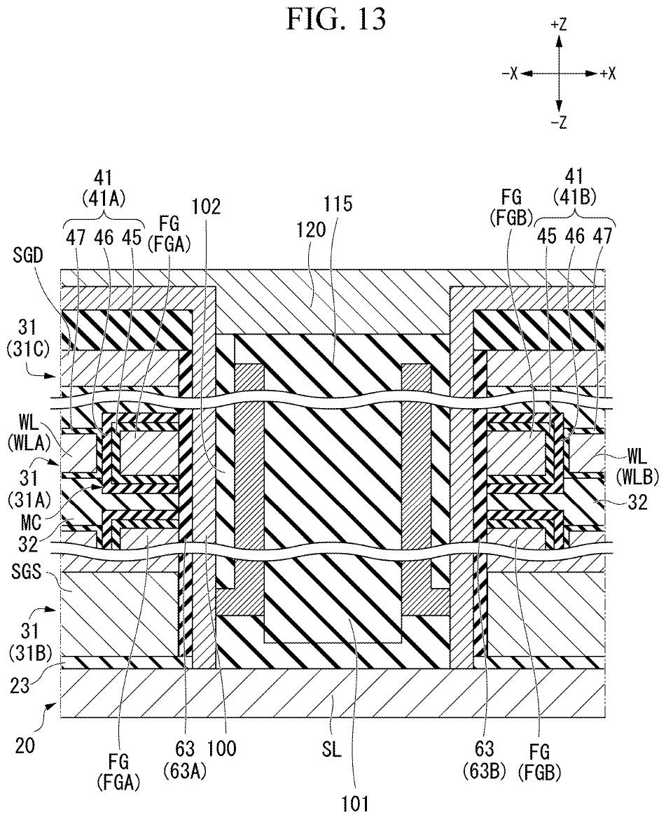

Next, in an eleventh process shown in FIG. 13, the insulating interlayer 115 is etched until the etching is completed at a position at which the channel interlayer 100 is exposed. Thereafter, a conductive film 120 is formed by a CVD method or the like so as to cover the laminate 30 from above.

Subsequently, in a twelfth process, inside the memory hole AH, the conductive film 120 is etched so that the conductive film 120 remains at the portion located inside the channel interlayer 100. The conductive film 120 that remains after etching functions as a contact interconnection that is to be connected to the aforementioned contact 91.

As stated above, in the embodiment, the configuration is adopted which includes: the back-gate electrode 64 provided on the opposite side of the floating gate electrode FG with respect to the channel 61; and the connection electrode 98 that connects the back-gate electrode 64 and the channel 61.

With this configuration, in a state where the source-side select gate line SGS is turned ON, the electrical potentials of the channel 61 and the back-gate electrode 64 can be fixed to the electrical potential of the source line SL. Consequently, an electrical line of force extending from a non-selected word line WL (the word line WL having an electrical potential higher than that of the selected the word line WL) adjacent to a selected word line WL passes through the channel 61 and thereafter extends toward the back-gate electrode 64. For this reason, the electrical line of force passing through the channel 61 is limited from wrapping around the selected word line WL, and therefore a threshold voltage of the selected word line WL is limited from being lowered. As a result, a cut-off performance of the selected word line WL can be improved, and therefore a distance between the word lines WL adjacent to one another in the Z direction can be reduced. Accordingly, miniaturization and high integration of the semiconductor storage device 1 can be improved.

On the other hand, since the back-gate electrode 64 is connected to the channel 61 with the connection electrode 98 interposed therebetween, in a state where the source-side select gate line SGS is turned OFF, electrical continuity between the source line SL and the back-gate electrode 64 is interrupted by the source-side select gate line SGS. Because of this, the channel 61 and the back-gate electrode 64 can be in a floating state. Therefore, an electrical potential of the channel 61 increases by bias of the word line WL (a so-called channel boost), and electron injection to the floating gate electrode FG can be prevented from being generated. As a result, incorrect writing can be suppressed.

Furthermore, in the embodiment, the back-gate electrode 64 and the channel 61 are connected at the position displaced from the cell region 71 in the Z direction.

Accordingly, unlike the case where any one of the cell structures MC and the connection electrode 98 are disposed to have the same height, it is possible to suppress the function of the cell structure MC from being inhibited by the connection electrode 98.

In the embodiment, the configuration is adopted in which the outer-circumferential end of the connection electrode 98 is connected to the portion of the channel 61 which faces the source-side select gate line SGS.

With this configuration, an insulation distance between the connection electrode 98 and the source-side select gate line SGS is shortened, and it is possible to quickly increase the electrical potential of the back-gate electrode 64 in accordance with, for example, an increase in voltage of the source-side select gate line SGS in a state where the source-side select gate line SGS is turned ON. That is, the responsivity of the back-gate electrode 64 can be improved, and the cut-off performance can be further improved.

In the embodiment, in plan view in the Z direction, the configuration is adopted in which the source-side select gate lines SGS extend to the positions at which the source-side select gate lines SGS overlap the floating gate electrodes FG.

With this configuration, it is possible to cause the source-side select gate line SGS to come close to the back-gate electrode 64. The responsivity of the back-gate electrode 64 can be improved, and the cut-off performance can be further improved.

In the embodiment, the configuration is adopted in which the length of the back-gate electrode 64 in the Z direction is shorter than the length of the channel 61.

With this configuration, an insulation distance between the back-gate electrode 64 and the bit line BL and an insulation distance between the back-gate electrode 64 and the source line SL are easily ensured, and channel boost is easily carried out.

In the embodiment, the configuration is adopted in which the back-gate electrode 64 is located outside the cell region 71 in the Z direction.

With this configuration, both the cut-off and the channel boost with respect to all of the cell structures MC can be improved.

In the embodiment, the configuration is adopted in which the back-gate electrode 64 is formed of polysilicon or crystalline silicon.

With this configuration, in a state where the source-side select gate line SGS is turned ON, the channel 61 and the back-gate electrode 64 can be in a floating state. Consequently, it is possible to reliably carry out the channel boost.

In the embodiment, the configuration is adopted in which the thickness T64 of the back-gate electrode 64 is larger than the thickness T61 of the channel 61.

With this configuration, the electroconductivity of the back-gate electrode 64 is improved, and the responsivity of the back-gate electrode 64 can be improved, and the cut-off performance can be further improved.

In the embodiment, the configuration is adopted in which the back-gate electrode 64 is an N-type semiconductor having an impurity concentration of 1×10¹⁷ cm⁻³ to 1×10²¹ cm⁻³.

With this configuration, the electroconductivity of the back-gate electrode 64 is improved, and the responsivity of the back-gate electrode 64 can be improved, and the cut-off performance can be further improved.

### Second Embodiment

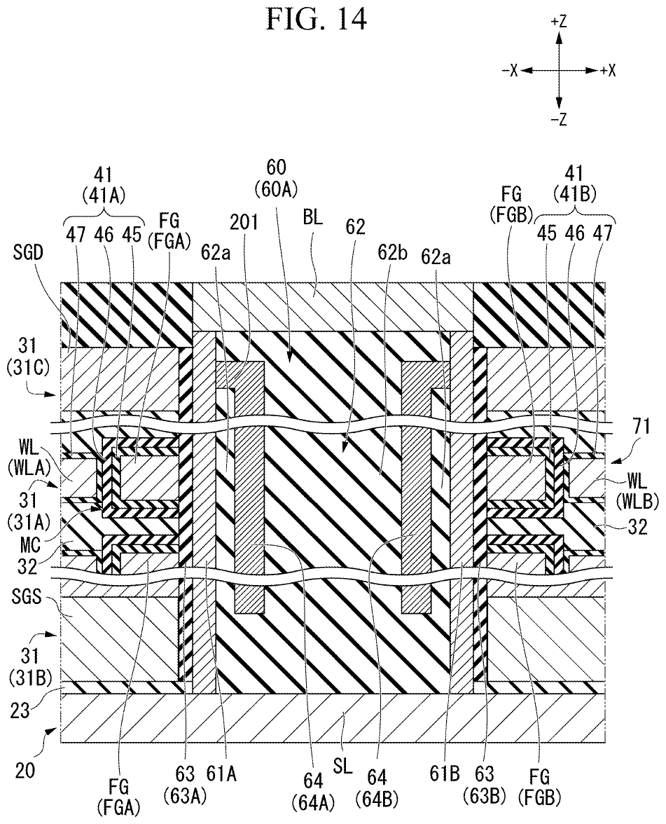

FIG. 14 is a cross-sectional view corresponding to FIG. 3 and showing a semiconductor storage device 200 according to a second embodiment. The embodiment is different from the aforementioned embodiment in that the back-gate electrode 64 and the channel 61 are connected via a connection electrode 201 at the upper end of the back-gate electrode 64.

In the semiconductor storage device 200 shown in FIG. 14, the back-gate electrode 64 is formed over an entire length of the cell region 71 in vertical cross section in the Z direction. The upper end of the back-gate electrode 64 is located above the cell region 71 inside the third functional layer 31C. The upper end of the back-gate electrode 64 faces the drain-side select gate line SGD in a state of interposing the channel 61 and the outer insulator 62a therebetween inside the third functional layer 31C. The drain-side select gate line SGD is an example of a second electrode. That is, the drain-side select gate line SGD is disposed on the opposite side of the silicon substrate 10 with respect to the word line WL that is furthest from the silicon substrate 10 in the word lines WL.

The lower end of the back-gate electrode 64 is located below the first functional layer 31A inside the second functional layer 31B. The lower end of the back-gate electrode 64 faces the source-side select gate line SGS in a state of interposing the channel 61, the outer insulator 62a, and the like therebetween. Note that, the lower end of the back-gate electrode 64 may be located above the source-side select gate line SGS.

A connection electrode 201 is provided at a position at which the upper end of the back-gate electrode 64 faces the drain-side select gate line SGD (a position at which they overlap each other in the Z direction). The connection electrode 201 extends from the upper end of the back-gate electrode 64 toward an outer-peripheral side of the pillar 60. The connection electrode 201 is in contact with the channel 61 at the outer-circumferential end (one end) and is in contact with the upper end of the back-gate electrode 64 at the other end located at an inner-peripheral side of the pillar 60. Particularly, the back-gate electrode 64 is connected to the bit line BL with the channel 61 interposed therebetween. Also in the embodiment, the connection electrode 201 protrudes from the entire periphery of the back-gate electrode 64 and is formed in a flange shape.

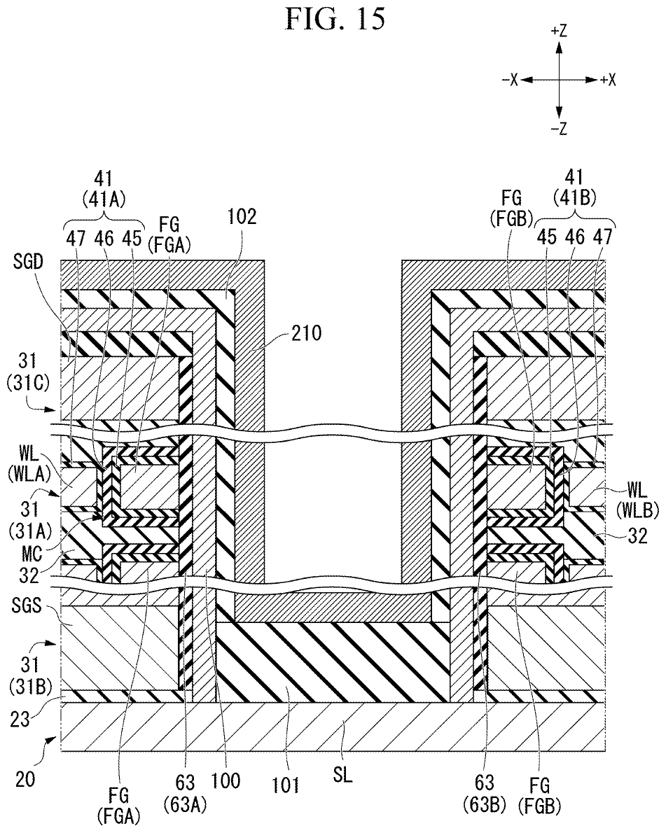

Next, a method of manufacturing the semiconductor storage device 200 according to the embodiment will be described. FIGS. 15 to 21 are operation flow charts each showing a cross section of the semiconductor storage device 200 corresponding to FIG. 14. The first process to the third process of the method of manufacturing the semiconductor storage device 200 according to the embodiment are the same as those of the above-mentioned first embodiment. Therefore, in the following explanation, the fourth process and the steps after the fourth process will be described.

In the fourth process shown in FIG. 15, an electrode intermediate product 210 is mainly formed on the insulating interlayers 101 and 102 by a CVD method or the like.

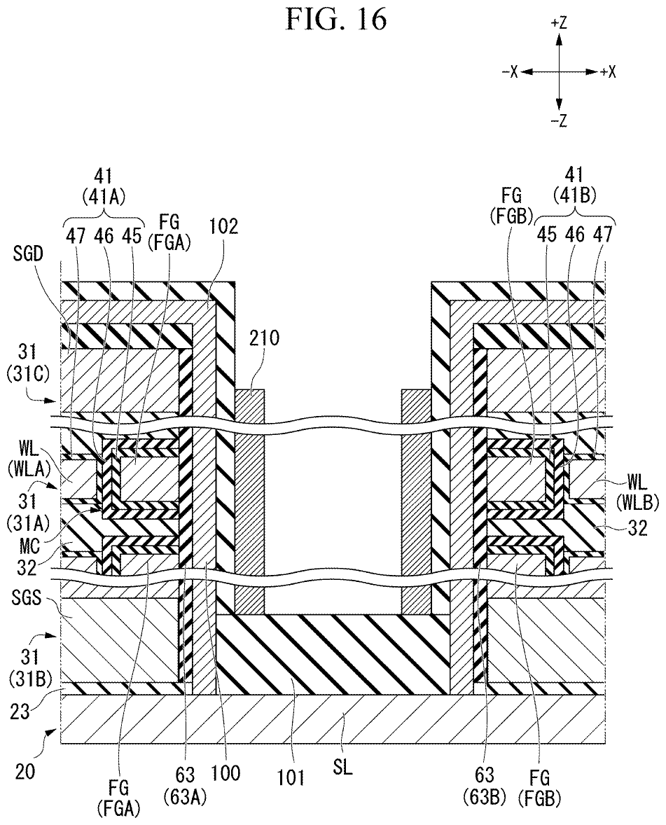

In a fifth process shown in FIG. 16, the electrode intermediate product 210 is etched back by RIE or the like. At this time, in the electrode intermediate product 210, the portion located at the position except for a region at which the back-gate electrode 64 is to be formed is removed.

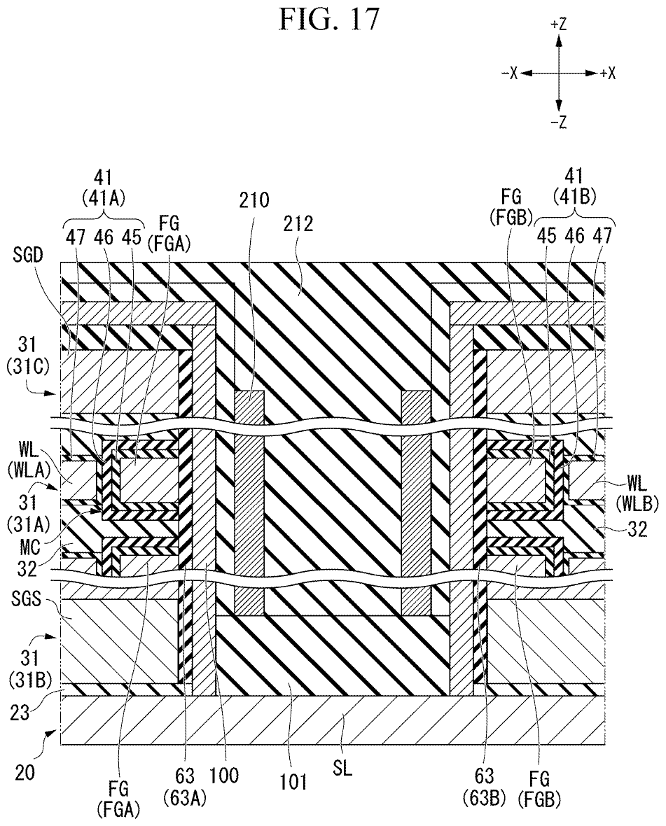

In a sixth process shown in FIG. 17, an insulating interlayer 212 that covers the electrode intermediate product 210 is formed on the insulating interlayers 101 and 102 by a CVD method or the like.

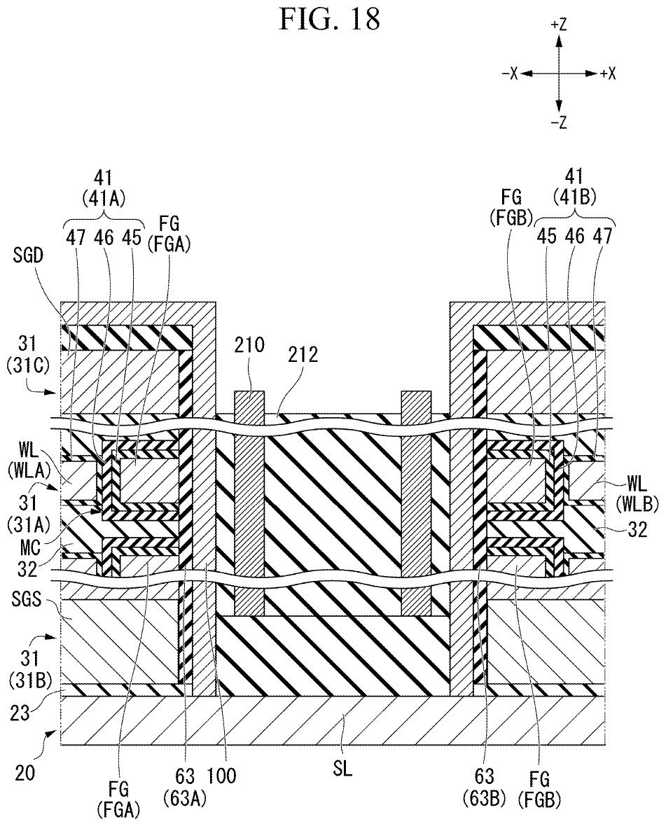

Subsequently, in a seventh process shown in FIG. 18, etching is carried out by, for example, using a chemical solution that dissolves silicon oxide, and the insulating interlayers 102 and 212 are mainly etched. At this time, the insulating interlayers 102 and 212 are removed until the etching is completed at a position at which an upper end of the electrode intermediate product 210 is exposed.

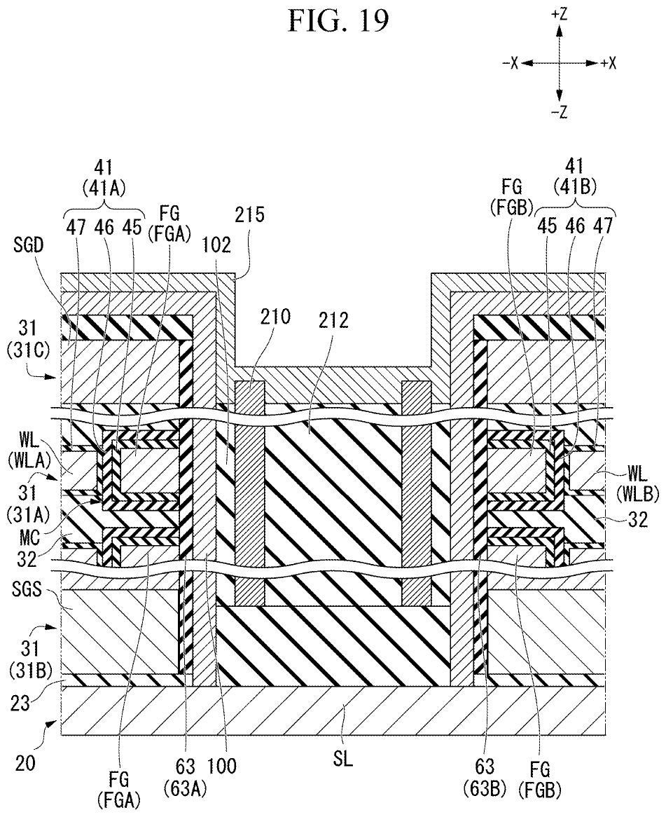

Next, in an eighth process shown in FIG. 19, the connection electrode 201 that connects the electrode intermediate product 210 (the back-gate electrode 64) to the channel interlayer 100 (the channel 61) is formed. Specifically, an electrode intermediate product 215 is mainly formed on the channel interlayer 100 and the insulating interlayers 102 and 212 by a CVD method or the like.

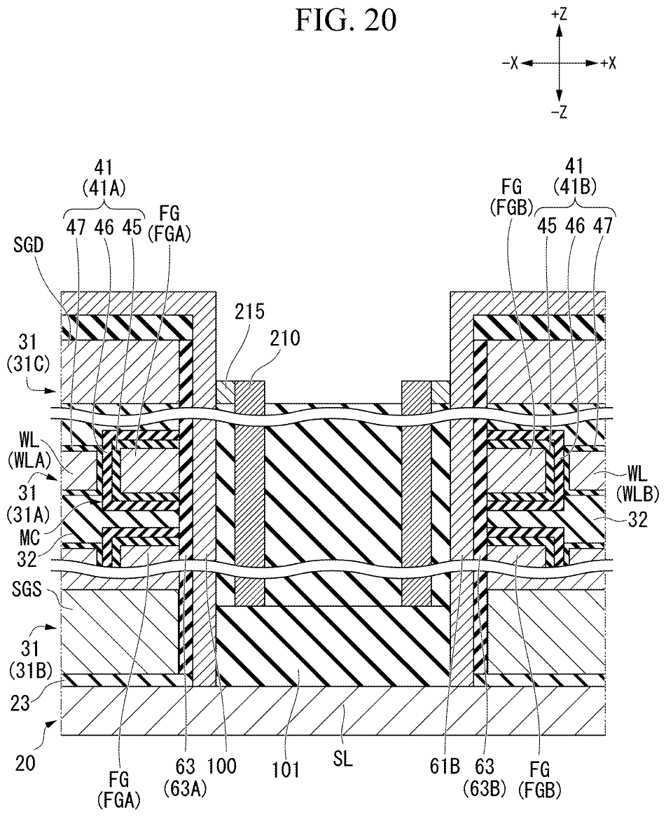

Thereafter, in a ninth process shown in FIG. 20, the electrode intermediate product 210 is etched back by RIE or the like so that the portion of the electrode intermediate product 215 which is located between the electrode intermediate product 210 and the channel interlayer 100 only remains.

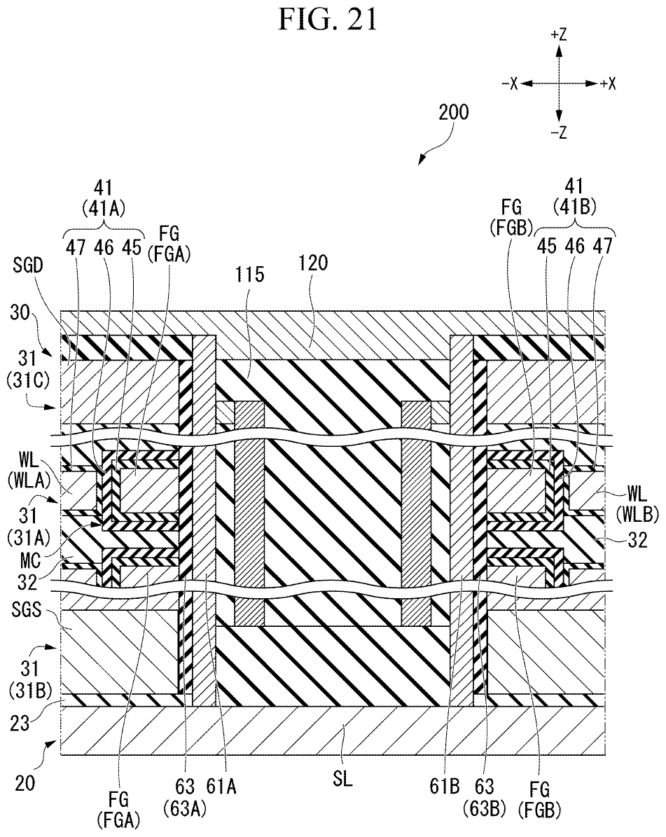

Next, as shown in FIG. 21, the insulating interlayer 115 or the conductive film 120 is formed by the same method of the tenth process to the eleventh process of the aforementioned first embodiment, and thereafter a contact electrode is formed by etching conductive film 120.

Also in the embodiment, the same actions and effects as those of the above-described embodiment can be obtained.

### Third Embodiment

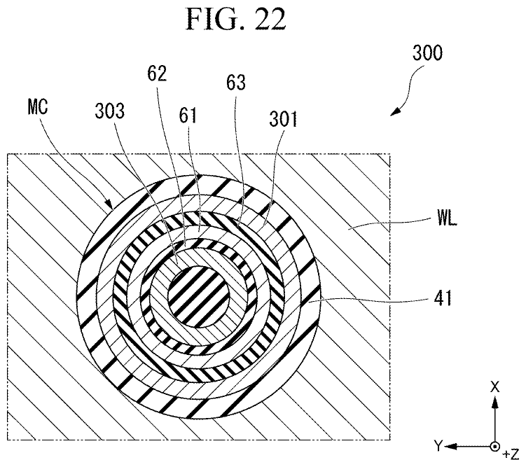

Next, a third embodiment will be described. FIG. 22 is a cross-sectional view showing an XY plane of a semiconductor storage device 300 according to a third embodiment. The semiconductor storage device 300 according to the embodiment is different from the aforementioned embodiments in that the aforementioned insulator 70 is not provided.

In the cell structure MC of the semiconductor storage device 300 shown in FIG. 22, a charge storage layer 301 is provided around the tunnel insulating film 63. The charge storage layer 301 has a so-called charge trap structure, surrounds the entire periphery of the tunnel insulating film 63, and extends in the Z direction. The charge storage layer 301 faces the word line WL with the block insulating film 41 interposed therebetween. Note that, the cell structure MC is not limited to the charge trap structure and may have a floating gate structure. The charge storage layer 301 is an example of a first charge storage part.

The back-gate electrode 303 extends in the Z direction inside the core insulator 62. Particularly, the back-gate electrode 303 is formed in a ring shape having a size smaller than the channel 61 in plan view. Similar to the aforementioned embodiments, the back-gate electrode 303 is connected to the channel 61 at an upper end and a lower end thereof via a connection electrode that is not shown in the drawings.

Also in the embodiment, the same actions and effects as those of the above-described embodiments can be obtained.

According to at least one embodiment described above, a plurality of first interconnection layers, a semiconductor layer, a first charge storage part, a conductor, and a connection portion are provided. The plurality of first interconnection layers extend in a first direction and are arrayed in a second direction intersecting the first direction. The semiconductor layer extends in the second direction and faces the plurality of first interconnection layers in a third direction intersecting the first direction and the second direction. The first charge storage part is provided between a first interconnection layer and the semiconductor layer. The conductor extends in the second direction on an opposite side of the first charge storage part with respect to the semiconductor layer. The connection portion has a first end that is in contact with the semiconductor layer and a second end that is in contact with the conductor.

This configuration provides the semiconductor storage device that can achieve further miniaturization and high integration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a plurality of first interconnection layers extending in a first direction and arrayed in a second direction intersecting the first direction;
a semiconductor layer extending in the second direction and facing the plurality of first interconnection layers in a third direction intersecting the first direction and the second direction;
a first charge storage part between a first interconnection layer and the semiconductor layer;
a conductor extending in the second direction on an opposite side of the first charge storage part with respect to the semiconductor layer; and
a connection portion having a first end in contact with the semiconductor layer and a second end in contact with the conductor.

2. The semiconductor storage device according to claim 1, further comprising an insulating layer between the conductor and the semiconductor layer.

3. The semiconductor storage device according to claim 1, further comprising:
a substrate; and
a first electrode between the substrate and one interconnection layer of the plurality of first interconnection layers, the interconnection layer being close to the substrate in the second direction; wherein
the first end of the connection portion is connected to a portion of the semiconductor layer, and the portion faces the first electrode in the third direction.

4. The semiconductor storage device according to claim 1, further comprising:
a substrate; and
a second electrode on an opposite side of the substrate with respect to one interconnection layer of the plurality of first interconnection layers, the interconnection layer being located away from the substrate in the second direction, wherein
the first end of the connection portion is connected to a portion of the semiconductor layer, and the portion faces the second electrode in the third direction.

5. The semiconductor storage device according to claim 1, further comprising:
a plurality of second interconnection layers next to the plurality of first interconnection layers in the third direction and arrayed in the second direction; and
a second charge storage part between a second interconnection layer and the semiconductor layer.

6. The semiconductor storage device according to claim 5, further comprising:
an insulator between the plurality of first interconnection layers and the plurality of second interconnection layers.

7. The semiconductor storage device according to claim 1, wherein
a length of the conductor in the second direction is shorter than a length of the semiconductor layer in the second direction.

8. The semiconductor storage device according to claim 5, wherein
the conductor has both end portions, and
both the end portions are located outside an outermost interconnection layer of the plurality of first interconnection layers in the second direction.

9. The semiconductor storage device according to claim 1, wherein
the conductor is formed of polysilicon or crystalline silicon.

10. The semiconductor storage device according to claim 1, wherein
a thickness of the conductor in the first direction is larger than a thickness of the semiconductor layer in the first direction.

11. The semiconductor storage device according to claim 1, wherein
the conductor is an N-type semiconductor having an impurity concentration of 1×10¹⁷ cm⁻³ to 1×10²¹ cm⁻³.
